(19) United States
(12) Patent Application Publication
(10) Pub. No.: US 2026/0196375 A1
(43) Pub. Date: Jul. 9, 2026

(54) LIQUID TRANSDUCER RADIOISOTOPE-POWERED NUCLEAR VOLTAIC SYSTEM

(71) Applicant: Nima Golsharifi, London (GB)

(72) Inventor: Nima Golsharifi, London (GB)

(73) Assignee: NUBATT PTE. LTD., Singapore (SG)

(21) Appl. No.: 19/556,533

(22) Filed: Mar. 4, 2026

(30) Foreign Application Priority Data
Mar. 6, 2025 (SG) 10202500575S

(51) Int. Cl. G21H 1/12; G01T 1/204; G21G 4/04; H10F 10/18; H10F 71/00; H10F 77/00; H10F 77/12; H10F 77/20; H10F 77/50

(52) U.S. Cl. CPC G21H 1/12; H10F 10/18; H10F 71/138; H10F 77/126; H10F 77/211; H10F 77/50; H10F 77/935; G01T 1/2042; G21G 4/04

(57) ABSTRACT

A nuclear voltaic power source utilizing liquid-state transducer media in combination with radioisotopes to convert nuclear radiation energy into electrical power. The system accommodates four types of liquid transducers: liquid semiconductors (e.g., selenium-iodide) that generate electron-hole pairs; liquid scintillators (e.g., liquid xenon) that convert radiation into photons subsequently absorbed by wide bandgap semiconductors; liquid metals (e.g., gallium) that produce free electrons through ionization; and ionic liquids that generate free ions under radiation exposure. An adaptive transducer contact interface (ATCI) adapts its charge extraction function to match the specific energy conversion mechanism of the selected transducer, functioning as an ohmic/Schottky contact, a wide bandgap semiconductor photon converter, or an electrolytic contact as appropriate. The modular architecture enables optimization for diverse applications while leveraging the inherent radiation resistance and self-healing properties of liquid transducers.

### CROSS-REFERENCE TO RELATED APPLICATIONS

This application claims the benefit of priority to Singapore Patent Application No. 10202500575S, filed Mar. 6, 2025, entitled “Liquid Transducer Radioisotope-Powered Nuclear Voltaic System,” the entire disclosure of which is hereby incorporated by reference.

### FIELD OF THE INVENTION

The present invention relates generally to nuclear power generation, and more specifically to a nuclear voltaic power source that utilizes liquid-state transducer media in combination with radioisotopes to convert nuclear radiation energy into electrical power. The liquid transducers include liquid semiconductors, liquid scintillators, liquid metals, and ionic liquids, each coupled with an adaptive transducer contact interface (ATCI) tailored to the specific charge generation and extraction mechanism of the transducer medium.

### BACKGROUND OF THE INVENTION

Nuclear voltaic systems convert the kinetic energy of particles emitted during radioactive decay into usable electrical energy. Traditional nuclear voltaic devices have relied primarily on solid-state semiconductor converters, such as silicon, silicon carbide, and gallium nitride p-n junctions. While effective, solid-state converters present limitations including radiation-induced lattice damage, reduced carrier lifetimes under prolonged irradiation, and mechanical inflexibility in harsh environments.

Liquid-state transducers offer fundamental advantages over their solid-state counterparts. Liquid semiconductors are inherently resistant to radiation damage because the liquid state lacks a rigid crystal lattice susceptible to displacement defects. Any radiation-induced disorder is rapidly self-healed by the thermal motion and fluidity of the liquid medium. This property enables sustained operation over the multi-decade timescales characteristic of long-lived radioisotopes.

Prior work has explored the use of individual liquid transducer types for nuclear energy conversion. For example, liquid selenium and liquid selenium-sulfur mixtures have been demonstrated as betavoltaic converters in laboratory settings. Separately, gaseous noble elements have been used as scintillation media in particle physics detectors, and ionic liquids have been studied for electrochemical energy storage.

However, no prior system has provided a unified device architecture that accommodates multiple distinct classes of liquid transducers—liquid semiconductors, liquid scintillators, liquid metals, and ionic liquids—within a single modular platform. Furthermore, prior liquid semiconductor nuclear cells have employed only simple ohmic or Schottky contact arrangements, without providing an adaptive contact interface capable of reconfiguring its functional role depending on the transducer medium employed. The present invention addresses these limitations.

### SUMMARY OF THE INVENTION

The present invention provides a nuclear voltaic power source comprising a radioisotope source, an interchangeable liquid transducer medium, and an adaptive transducer contact interface (ATCI). The ATCI is configured to adapt its charge extraction function to match the specific energy conversion mechanism of the selected liquid transducer, thereby enabling a single device platform to operate with any of at least four fundamentally different liquid transducer types.

In a first configuration, the liquid transducer comprises a liquid semiconductor, such as a selenium-iodide mixture, that generates electron-hole pairs upon exposure to ionizing radiation. The ATCI functions as an ohmic or Schottky contact layer to extract the photogenerated carriers.

In a second configuration, the liquid transducer comprises a liquid scintillator, such as liquid xenon or an organic scintillator fluid, that converts radiation energy into photons via scintillation. The ATCI functions as a wide bandgap semiconductor photon converter (e.g., GaN, SiC, diamond, or Ga₂O₃) positioned adjacent to the scintillator to absorb the scintillation photons and generate electron-hole pairs for electrical extraction.

In a third configuration, the liquid transducer comprises a liquid metal, such as gallium, wherein radiation-induced ionization produces free electrons and metal ions. The ATCI functions as an ohmic contact for direct charge extraction.

In a fourth configuration, the liquid transducer comprises an ionic liquid that undergoes increased ionization upon radiation exposure, creating free ions. The ATCI functions as an electrolytic contact layer that applies a potential difference across the ionic liquid to facilitate ion collection and current generation.

The system further includes an ultra-thin glass encapsulation layer surrounding the radioisotope source, a chemically bonded glass sealing layer, a silicon chip housing providing thermal stability, and an external protective casing. The device geometry is configured so that the length of the radioisotope source matches the radiation interaction range within the liquid transducer, maximizing energy absorption.

### DETAILED DESCRIPTION OF THE INVENTION

### Radioisotope Source

The system utilizes at least one radioisotope selected from the group including, but not limited to: Ni-63, Am-241, Pu-238, Sr-90, Cs-137, Co-60, H-3, Kr-85, Po-210, C-14, Ar-39, Si-32, Fe-55, Pm-147, and combinations thereof. The radioisotope is selected based on its emission type (alpha, beta, or gamma), half-life, specific activity, and compatibility with the chosen liquid transducer medium. The radioisotope is positioned centrally within the device and is designed to match the length of the device structure, ensuring optimal radiation interaction within the adjacent liquid transducer layer.

The radioisotope is enclosed within an ultra-thin glass encapsulation (element 2) that allows radiation to pass through while securely containing the radioactive material. The glass thickness is minimized to reduce attenuation, enabling efficient radiation transfer to the liquid transducer layer while maintaining complete containment of the radioactive source material.

### Liquid Semiconductor Transducer

In the liquid semiconductor configuration, the transducer layer (element 3) comprises a liquid semiconductor material that directly converts radiation energy into electron-hole pairs. The liquid semiconductor may be selected from compounds including, but not limited to: selenium-iodide (SeI₂, melting point approximately 57° C., bandgap approximately 1.41 eV), selenium-sulfur (SeS, melting point approximately 105° C., bandgap approximately 2.0-2.8 eV), copper selenide (Cu₂Se), silver telluride (Ag₂Te), thallium selenide (Tl₂Se), germanium selenide (GeSe), indium selenide (InSe), antimony triselenide (Sb₂Se₃), and vanadium pentoxide (V₂O₅).

The selenium-iodide mixture is particularly advantageous due to its low melting point, which enables operation at near-ambient temperatures while maintaining semiconducting behavior. The equal-atomic-fraction selenium-iodine mixture depresses the melting point to approximately 57° C. while preserving a conductivity gap characteristic of a true liquid semiconductor. The iodine caps the ends of selenium chains, maintaining the short-range order necessary for semiconducting behavior in the liquid state.

The liquid semiconductor is contained within a corrosion-resistant structure, such as silicon or glass, which prevents chemical reactions with the semiconductor material and ensures thermal stability. The ATCI layer (element 4) is configured as an ohmic contact (e.g., titanium, nickel, or graphene-coated metal) or a Schottky contact layer for efficient extraction of the radiation-generated electron-hole pairs.

### Liquid Scintillator Transducer

In the liquid scintillator configuration, the transducer layer comprises a liquid scintillator medium that converts radiation energy into photons via scintillation. The scintillator may be selected from: liquid xenon (LXe), liquid krypton (LKr), liquid argon (LAr), liquid neon (LNe), organic scintillator fluids (e.g., pseudocumene-based, linear alkylbenzene-based, or toluene-based scintillators), and combinations thereof.

Liquid xenon is particularly advantageous due to its high scintillation yield (approximately 40,000-70,000 photons per MeV of deposited energy), fast scintillation response (approximately 2-45 nanoseconds), high atomic number (Z=54) providing efficient radiation stopping power, and emission wavelength centered at approximately 175 nm in the vacuum ultraviolet range.

In this configuration, the ATCI layer functions as a wide bandgap semiconductor photon converter positioned adjacent to the liquid scintillator. The wide bandgap semiconductor is selected to have a bandgap energy matched to or exceeding the scintillation emission energy, and may comprise silicon carbide (SiC, bandgap approximately 3.26 eV), gallium nitride (GaN, bandgap approximately 3.4 eV), aluminum nitride (AlN, bandgap approximately 6.2 eV), diamond (bandgap approximately 5.47 eV), gallium oxide (Ga₂O₃, bandgap approximately 4.8-4.9 eV), or boron carbide (B₄C, bandgap approximately 2.09 eV). The scintillation photons are absorbed by the wide bandgap semiconductor, generating electron-hole pairs that are extracted as electrical current.

### Liquid Metal Transducer

In the liquid metal configuration, the transducer layer comprises a liquid metal such as gallium (melting point approximately 29.76° C.), gallium-indium eutectic (melting point approximately 15.5° C.), or other low-melting-point metallic systems. When exposed to ionizing radiation, the liquid metal undergoes ionization, producing free electrons and metal ions. The ATCI layer is configured as an ohmic contact for direct and efficient charge extraction.

Gallium is particularly advantageous as a liquid metal transducer due to its low melting point, low vapor pressure, and ability to remain liquid over a wide temperature range (approximately 29.76° C. to 2204° C.). The high density of gallium (approximately 5.91 g/cm³) provides effective radiation stopping power.

### Ionic Liquid Transducer

In the ionic liquid configuration, the transducer layer comprises an ionic liquid that exhibits increased ionization upon radiation exposure. Ionic liquids are room-temperature molten salts composed entirely of ions, possessing negligible vapor pressure, high thermal stability, and engineered charge transport properties. When irradiated, the ionic liquid generates free ions that contribute to increased ionic conductivity.

Suitable ionic liquids include, but are not limited to: 1-butyl-3-methylimidazolium bis(trifluoromethylsulfonyl)imide ([BMIM][Tf₂N]), 1-ethyl-3-methylimidazolium tetrafluoroborate ([EMIM][BF₄]), 1-butyl-3-methylimidazolium hexafluorophosphate ([BMIM][PF₆]), and related imidazolium, pyrrolidinium, or phosphonium-based ionic liquids. The ATCI layer functions as an electrolytic contact layer, applying a potential difference across the ionic liquid to facilitate directional ion migration, collection, and current generation. The electrode materials may comprise indium tin oxide (ITO), molybdenum, or graphene-coated electrodes to enhance conductivity and stability during ion collection.

### Adaptive Transducer Contact Interface (ATCI)

The adaptive transducer contact interface (ATCI, element 4) is a critical feature of the present invention that enables a single device architecture to accommodate multiple distinct liquid transducer types. The ATCI is positioned in contact with the liquid transducer layer and adapts its functional role to match the charge generation and extraction requirements of the selected transducer medium.

The ATCI may be configured as one of: (a) a wide bandgap semiconductor layer (e.g., GaN, SiC, diamond, AlN, Ga₂O₃) in liquid scintillator configurations, where it captures scintillation photons and converts them to electron-hole pairs; (b) an ohmic or Schottky contact layer (e.g., titanium, nickel, graphene-coated metals) in liquid semiconductor and liquid metal configurations, providing efficient direct charge extraction; or (c) an electrolytic contact layer (e.g., ITO, molybdenum, graphene-coated electrodes) in ionic liquid configurations, facilitating ion collection under an applied potential difference.

### Device Structure and Containment

The complete device structure comprises, from the center outward: (1) the radioisotope layer (element 1), centrally positioned; (2) ultra-thin glass encapsulation (element 2) surrounding the radioisotope, providing containment while permitting radiation transmission; (3) the interchangeable liquid transducer layer (element 3); (4) the adaptive transducer contact interface (element 4); (5) a chemically bonded glass sealing layer (element 5) that seals internal components and prevents environmental contamination; (6) a silicon chip housing (element 6) forming the base structure and providing thermal stability; and (7) an external casing (element 7) providing structural integrity and radiation shielding.

The device length is tuned to align with the radiation range of the selected radioisotope, ensuring maximal energy absorption within the transducer layer. For beta-emitting isotopes, the transducer layer thickness is selected to be approximately equal to or greater than the maximum beta particle range in the liquid medium. For alpha-emitting isotopes, the transducer layer thickness accounts for the shorter penetration depth of alpha particles.

### BRIEF DESCRIPTION OF THE DRAWINGS

FIG. 1 is a cross-sectional view of the nuclear voltaic device showing the layered architecture with the centrally positioned radioisotope layer, ultra-thin glass encapsulation, interchangeable liquid transducer layer, adaptive transducer contact interface, glass sealing layer, silicon chip housing, and external casing.

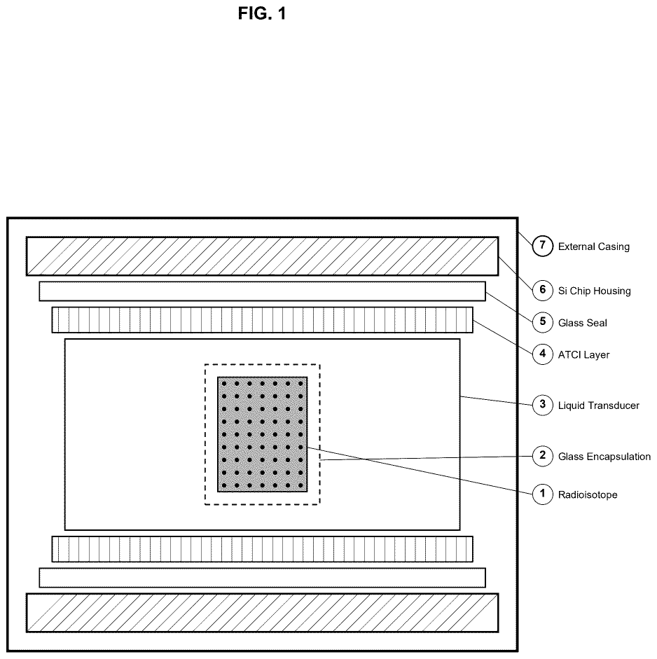

FIG. 2 is a detailed cross-sectional view of the central radioisotope layer with ultra-thin glass encapsulation showing radiation transmission through the glass to the liquid transducer.

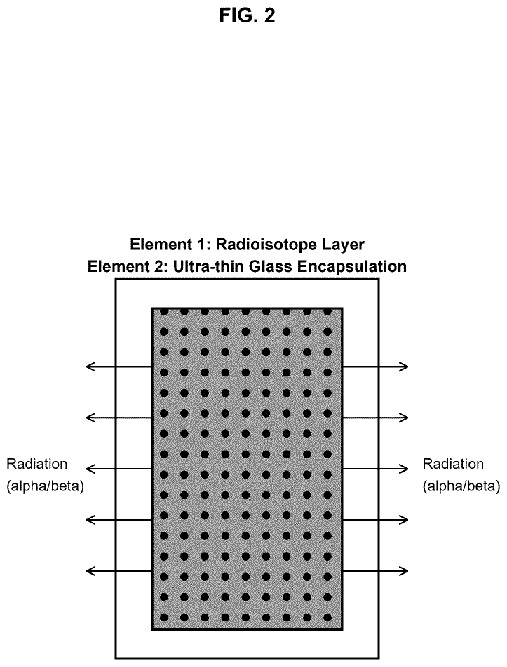

FIG. 3 is a cross-sectional view of the liquid semiconductor configuration showing the selenium-iodide transducer with ohmic/Schottky ATCI contacts.

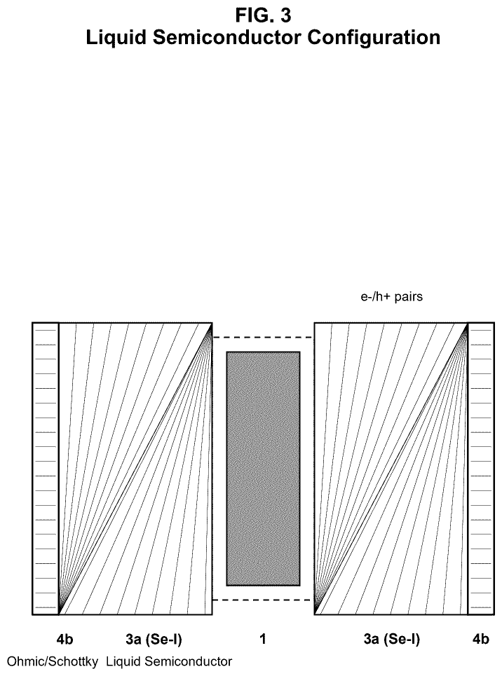

FIG. 4 is a cross-sectional view of the liquid scintillator configuration showing the scintillator transducer with wide bandgap semiconductor ATCI for photon-to-electron conversion.

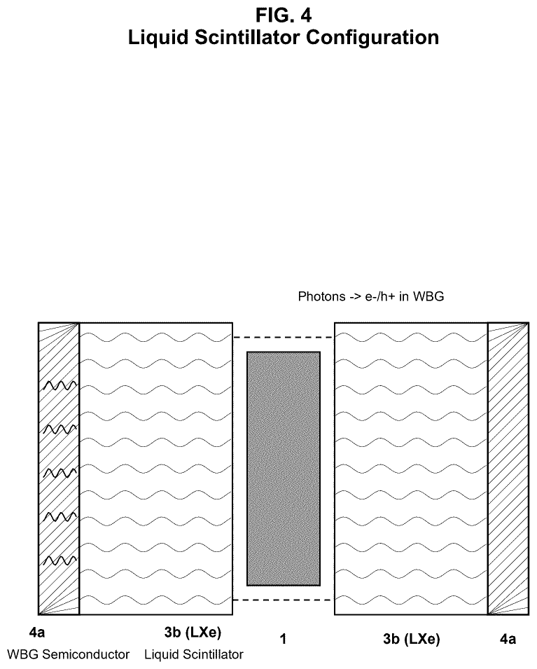

FIG. 5 is a cross-sectional view of the ionic liquid configuration showing the ionic liquid transducer with electrolytic ATCI contacts.

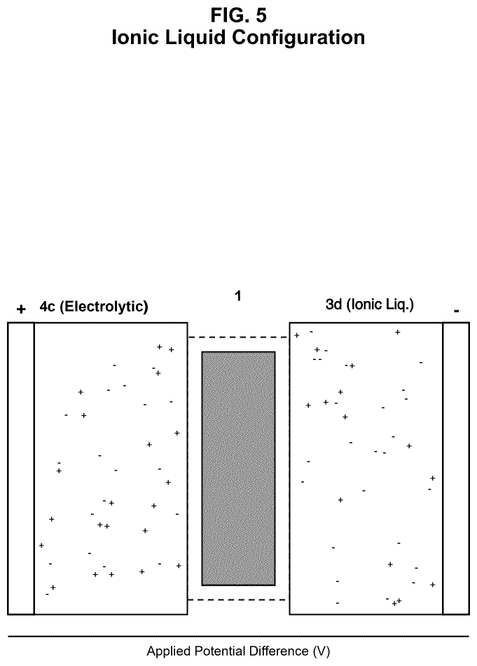

FIG. 6 is a cross-sectional view of the liquid metal configuration showing the gallium transducer with ohmic ATCI contacts.

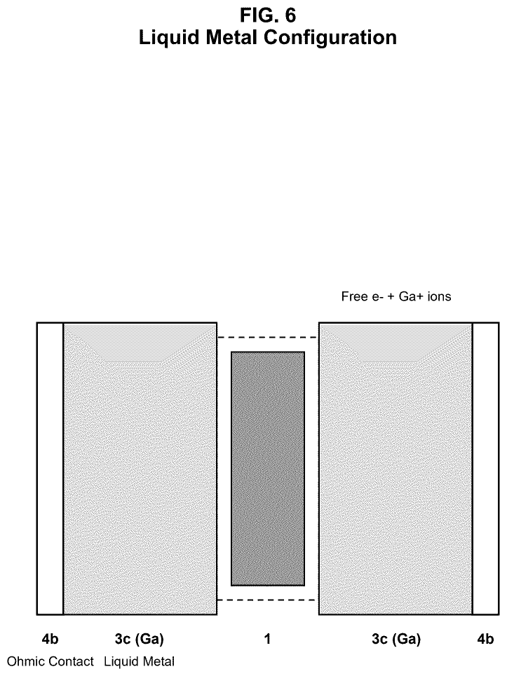

FIG. 7 is a view of the external containment and casing structure.

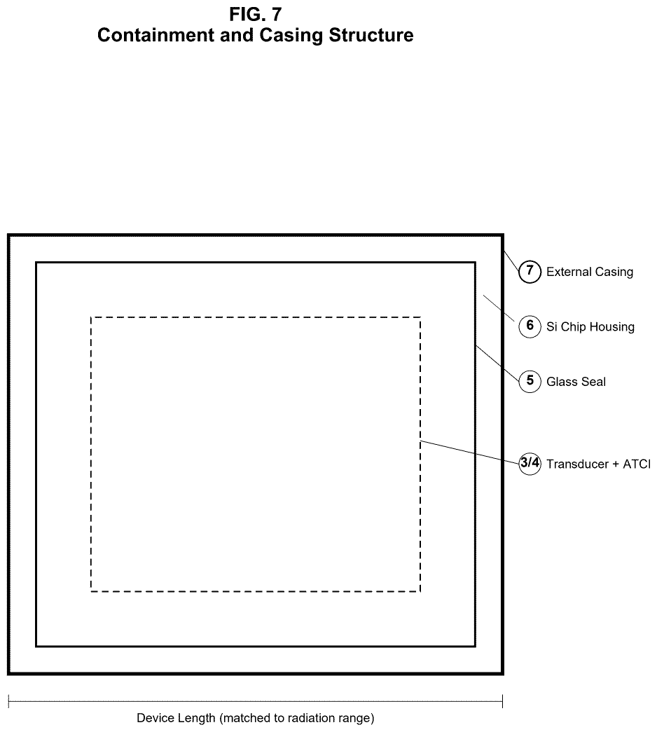

FIG. 8 is a parts reference table listing all reference numerals and corresponding component descriptions.

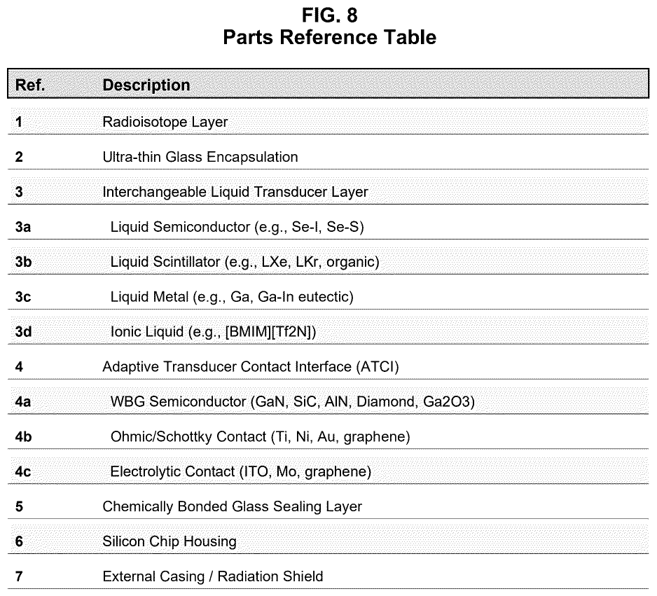

FIG. 9 is a schematic diagram showing the energy conversion pathways for each of the four liquid transducer configurations.

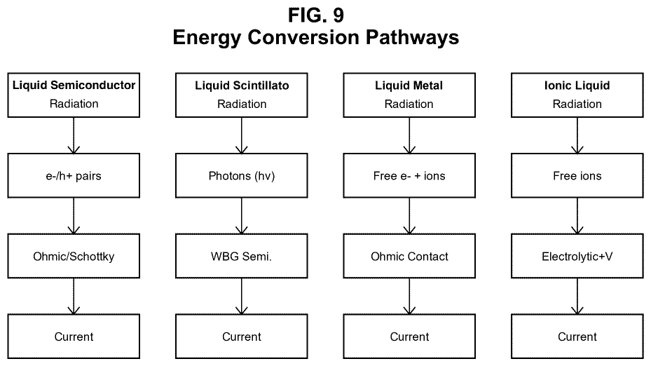

FIG. 10 is a schematic diagram showing a series-parallel connection of multiple liquid transducer nuclear voltaic cells for scalable power output.

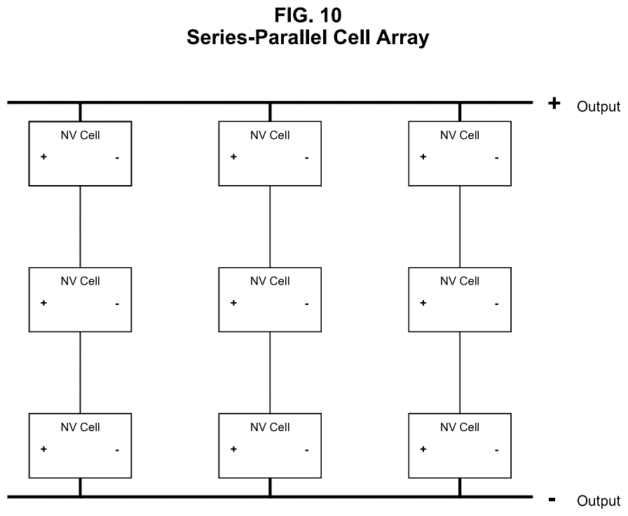

What is claimed is:

1. A nuclear voltaic power source comprising:
(a) at least one radioisotope source configured to emit ionizing radiation;
(b) an ultra-thin glass encapsulation layer surrounding the radioisotope source, the glass encapsulation permitting transmission of the ionizing radiation while containing the radioisotope;
(c) a liquid transducer layer disposed adjacent to the glass encapsulation layer, the liquid transducer layer comprising a liquid-state medium selected from the group consisting of: a liquid semiconductor, a liquid scintillator, a liquid metal, and an ionic liquid, the liquid transducer layer converting energy from the ionizing radiation into at least one of electron-hole pairs, photons, free electrons with metal ions, or free ions; and
(d) an adaptive transducer contact interface (ATCI) layer disposed adjacent to the liquid transducer layer, wherein the ATCI layer is configured to extract electrical charge from the liquid transducer layer by adapting its charge extraction function to match the energy conversion mechanism of the selected liquid-state medium.

2. The nuclear voltaic power source of claim 1, wherein the liquid transducer layer comprises a liquid semiconductor selected from the group consisting of selenium-iodide, selenium-sulfur, copper selenide, silver telluride, thallium selenide, germanium selenide, indium selenide, antimony triselenide, and vanadium pentoxide, and wherein the ATCI layer comprises an ohmic contact or a Schottky contact configured for extraction of radiation-generated electron-hole pairs.

3. The nuclear voltaic power source of claim 2, wherein the liquid semiconductor comprises a selenium-iodide mixture having a melting point of approximately 57° C. and a bandgap of approximately 1.41 eV, contained within a corrosion-resistant structure comprising silicon or glass.

4. The nuclear voltaic power source of claim 1, wherein the liquid transducer layer comprises a liquid scintillator selected from the group consisting of liquid xenon, liquid krypton, liquid argon, liquid neon, organic scintillator fluids, and combinations thereof, and wherein the ATCI layer comprises a wide bandgap semiconductor configured to absorb scintillation photons generated by the liquid scintillator and to convert the scintillation photons into electron-hole pairs for electrical extraction.

5. The nuclear voltaic power source of claim 4, wherein the wide bandgap semiconductor of the ATCI layer is selected from the group consisting of silicon carbide, gallium nitride, aluminum nitride, diamond, gallium oxide, and boron carbide.

6. The nuclear voltaic power source of claim 4, wherein the liquid scintillator comprises liquid xenon having a scintillation yield of approximately 40,000 to 70,000 photons per MeV and an emission wavelength centered at approximately 175 nm.

7. The nuclear voltaic power source of claim 1, wherein the liquid transducer layer comprises a liquid metal selected from the group consisting of gallium, gallium-indium eutectic, and gallium-indium-tin alloy, and wherein the ATCI layer comprises an ohmic contact configured for extraction of radiation-generated free electrons and metal ions.

8. The nuclear voltaic power source of claim 1, wherein the liquid transducer layer comprises an ionic liquid, and wherein the ATCI layer comprises an electrolytic contact layer configured to apply a potential difference across the ionic liquid to facilitate directional ion migration and current generation.

9. The nuclear voltaic power source of claim 8, wherein the ionic liquid is selected from the group consisting of 1-butyl-3-methylimidazolium bis(trifluoromethylsulfonyl)imide, 1-ethyl-3-methylimidazolium tetrafluoroborate, 1-butyl-3-methylimidazolium hexafluorophosphate, and related imidazolium-based, pyrrolidinium-based, and phosphonium-based ionic liquids.

10. The nuclear voltaic power source of claim 8, wherein the electrolytic contact layer comprises electrodes selected from indium tin oxide, molybdenum, and graphene-coated electrodes.

11. A nuclear voltaic power source comprising:
a radioisotope enclosed within an ultra-thin glass encapsulation;
a liquid transducer chamber configured to receive an interchangeable liquid-state transducer medium adjacent to the glass encapsulation; and
an adaptive transducer contact interface (ATCI) layer adjacent to the liquid transducer chamber, the ATCI layer being selectively configurable as: (i) a wide bandgap semiconductor photon converter when the liquid-state transducer medium is a liquid scintillator; (ii) an ohmic or Schottky contact layer when the liquid-state transducer medium is a liquid semiconductor or liquid metal; or (iii) an electrolytic contact layer when the liquid-state transducer medium is an ionic liquid.

12. The nuclear voltaic power source of claim 11, further comprising a chemically bonded glass sealing layer enclosing the liquid transducer chamber and ATCI layer, a silicon chip housing providing thermal stability, and an external casing providing structural integrity and radiation shielding.

13. The nuclear voltaic power source of claim 11, wherein the radioisotope is selected from the group consisting of Ni-63, Am-241, Pu-238, Sr-90, Cs-137, Co-60, H-3, Kr-85, Po-210, C-14, Ar-39, Si-32, Fe-55, and Pm-147.

14. The nuclear voltaic power source of claim 11, wherein a length of the radioisotope matches a radiation interaction range within the liquid-state transducer medium to maximize energy absorption.

15. The nuclear voltaic power source of claim 11, wherein the liquid scintillator produces scintillation photons upon irradiation and the wide bandgap semiconductor photon converter absorbs the scintillation photons and generates electrical current therefrom.

16. A method of converting nuclear radiation energy into electrical power, the method comprising:
(a) providing at least one radioisotope source enclosed within an ultra-thin glass encapsulation layer;
(b) disposing a liquid-state transducer medium adjacent to the glass encapsulation layer, the liquid-state transducer medium selected from the group consisting of a liquid semiconductor, a liquid scintillator, a liquid metal, and an ionic liquid;
(c) converting ionizing radiation from the radioisotope into at least one of electron-hole pairs, photons, free electrons with metal ions, or free ions within the liquid-state transducer medium; and
(d) extracting electrical charge from the liquid-state transducer medium through an adaptive transducer contact interface (ATCI) layer configured to match the charge extraction function to the energy conversion mechanism of the selected liquid-state transducer medium.

17. The method of claim 16, wherein step (b) comprises disposing liquid xenon as the liquid scintillator medium, and step (c) comprises converting the ionizing radiation into vacuum ultraviolet photons via scintillation at approximately 175 nm, and step (d) comprises absorbing the vacuum ultraviolet photons in a wide bandgap semiconductor layer and extracting photogenerated electron-hole pairs.

18. The method of claim 16, wherein step (b) comprises disposing a selenium-iodide liquid semiconductor as the liquid-state transducer medium, and step (d) comprises extracting electron-hole pairs through an ohmic or Schottky contact.

19. The method of claim 16, wherein step (b) comprises disposing an ionic liquid as the liquid-state transducer medium, and step (d) comprises applying a potential difference across the ionic liquid through an electrolytic contact layer to collect radiation-generated ions and generate current.

20. The method of claim 16, wherein step (b) comprises disposing a liquid metal comprising gallium as the liquid-state transducer medium, and step (d) comprises extracting free electrons and metal ions through an ohmic contact.

21. A nuclear voltaic power source comprising:
a radioisotope source configured to emit ionizing radiation;
a liquid scintillator transducer disposed to receive the ionizing radiation, the liquid scintillator generating scintillation photons upon interaction with the ionizing radiation;
a wide bandgap semiconductor layer disposed adjacent to the liquid scintillator transducer, the wide bandgap semiconductor layer absorbing the scintillation photons and generating electron-hole pairs therefrom; and
electrical contacts configured to extract current from the wide bandgap semiconductor layer.

22. The nuclear voltaic power source of claim 21, wherein the liquid scintillator comprises liquid xenon and the wide bandgap semiconductor comprises gallium nitride or aluminum nitride having a bandgap energy matched to or exceeding the scintillation emission energy.

23. The nuclear voltaic power source of claim 21, wherein the liquid scintillator comprises an organic scintillator fluid and the wide bandgap semiconductor comprises silicon carbide or gallium nitride.

24. The nuclear voltaic power source of claim 21, further comprising an ultra-thin glass encapsulation layer surrounding the radioisotope source, a chemically bonded glass sealing layer, and an external casing.

25. The nuclear voltaic power source of claim 21, wherein the radioisotope is an alpha emitter and the liquid scintillator is dimensioned so that the alpha particle range is substantially contained within the liquid scintillator volume.

26. A nuclear voltaic power source comprising:
a radioisotope source configured to emit ionizing radiation;
an ionic liquid transducer layer disposed to receive the ionizing radiation, the ionic liquid undergoing radiation-induced ionization to produce free ions;
a pair of electrodes disposed on opposing sides of the ionic liquid transducer layer, the electrodes applying a potential difference across the ionic liquid to facilitate directional migration of the radiation-generated free ions; and
an external circuit connected to the pair of electrodes for extracting electrical current generated by the directional ion migration.

27. The nuclear voltaic power source of claim 26, wherein the ionic liquid comprises an imidazolium-based ionic liquid selected from 1-butyl-3-methylimidazolium bis(trifluoromethylsulfonyl)imide and 1-ethyl-3-methylimidazolium tetrafluoroborate.

28. The nuclear voltaic power source of claim 26, wherein the electrodes comprise indium tin oxide, molybdenum, or graphene-coated metal electrodes.

29. The nuclear voltaic power source of claim 26, wherein the ionic liquid exhibits negligible vapor pressure and remains thermally stable at temperatures up to at least 200° C.

30. The nuclear voltaic power source of claim 26, further comprising an ultra-thin glass encapsulation layer surrounding the radioisotope source and a containment structure housing the ionic liquid transducer layer.
